(19) United States
(12) Patent Application Publication
(10) Pub. No.: US 2024/0186997 A1
(43) Pub. Date: Jun. 6, 2024

(54) VOLTAGE GENERATION CIRCUIT

(71) Applicant: ROHM CO., LTD., Kyoto (JP)

(72) Inventors: Koji SAITO, Kyoto (JP); Ryoichi KUROKAWA, Kyoto (JP)

(21) Appl. No.: 18/525,125

(22) Filed: Nov. 30, 2023

(30) Foreign Application Priority Data
Dec. 1, 2022 (JP) 2022-192931

(51) Int. Cl. H03K 17/687; H03K 5/01

(52) U.S. Cl. CPC H03K 17/6871; H03K 5/01

(57) ABSTRACT

A voltage generation circuit includes: a first MOSFET including a source, a back gate, and a gate connected to a first node, and a drain connected to a first potential end; a front-stage transistor circuit including one or more second MOSFETs and connected between the first node and a second potential end; a third MOSFET including a source and a back gate connected to a second node, a gate connected to the first node, and a drain connected to the first potential end; and a rear-stage transistor circuit including one or more fourth MOSFETs and connected between the second node and the second potential end, wherein the first and third MOSFETs each have characteristic of being in a conductive state when gate-source voltage is 0 V, and wherein the second and fourth MOSFETs each have characteristic of being in a cut-off state when gate-source voltage is 0 V.

### CROSS-REFERENCE TO RELATED APPLICATION

This application is based upon and claims the benefit of priority from Japanese Patent Application No. 2022-192931, filed on Dec. 1, 2022, the entire contents of which are incorporated herein by reference.

### TECHNICAL FIELD

The present disclosure relates to a voltage generation circuit.

### BACKGROUND

A voltage generation circuit is provided in many electronic circuits. The voltage generation circuit generates an output voltage having a desired voltage value based on an applied voltage.

### BRIEF DESCRIPTION OF DRAWINGS

The accompanying drawings, which are incorporated in and constitute a part of the specification, illustrate embodiments of the present disclosure.

FIG. 1 is a configuration diagram of a voltage generation circuit according to a first embodiment of the present disclosure.

FIG. 2 is a configuration diagram of a voltage generation circuit according to a first reference example.

FIG. 3 is a diagram showing start-up characteristics of the voltage generation circuit according to the first reference example.

FIG. 4 is a configuration diagram of a voltage generation circuit according to Example EX1A belonging to the first embodiment of the present disclosure.

FIG. 5 is a diagram for explaining a behavior of the voltage generation circuit at start-up, according to Example EX1A belonging to the first embodiment of the present disclosure.

FIG. 6 is a diagram showing start-up characteristics of the voltage generation circuit according to the first reference example and start-up characteristics of the voltage generation circuit according to the first embodiment of the present disclosure.

FIG. 7 is a configuration diagram of a voltage generation circuit according to Example EX1B belonging to the first embodiment of the present disclosure.

FIG. 8 is a configuration diagram of a voltage generation circuit according to Example EX1C belonging to the first embodiment of the present disclosure.

FIG. 9 is a configuration diagram of the voltage generation circuit according to Example EX1C belonging to the first embodiment of the present disclosure (where m=n=2).

FIG. 10 is a configuration diagram of a voltage generation circuit according to Example EX1D belonging to the first embodiment of the present disclosure.

FIG. 11 is a configuration diagram of the voltage generation circuit according to Example EX1D belonging to the first embodiment of the present disclosure (where m=n=2).

FIG. 12 is a configuration diagram of a voltage generation circuit according to Example EX1E belonging to the first embodiment of the present disclosure.

FIG. 13 is a configuration diagram of the voltage generation circuit according to Example EX1E belonging to the first embodiment of the present disclosure (where m=n=2).

FIG. 14 is a configuration diagram of a voltage generation circuit according to a second embodiment of the present disclosure.

FIG. 15 is a configuration diagram of a voltage generation circuit according to a second reference example.

FIG. 16 is a diagram showing start-up characteristics of the voltage generation circuit according to the second reference example.

FIG. 17 is a configuration diagram of a voltage generation circuit according to Example EX2A belonging to the second embodiment of the present disclosure.

FIG. 18 is a diagram for explaining a behavior of the voltage generation circuit at start-up, according to Example EX2A belonging to the second embodiment of the present disclosure.

FIG. 19 is a diagram showing start-up characteristics of the voltage generation circuit according to the second reference example and start-up characteristics of the voltage generation circuit according to the second embodiment of the present disclosure.

FIG. 20 is a configuration diagram of a voltage generation circuit according to Example EX2B belonging to the second embodiment of the present disclosure.

FIG. 21 is a configuration diagram of a voltage generation circuit according to Example EX2C belonging to the second embodiment of the present disclosure.

FIG. 22 is a configuration diagram of the voltage generation circuit according to Example EX2C belonging to the second embodiment of the present disclosure (where m=n=2).

FIG. 23 is a configuration diagram of a voltage generation circuit according to Example EX2D belonging to the second embodiment of the present disclosure.

FIG. 24 is a configuration diagram of the voltage generation circuit according to Example EX2D belonging to the second embodiment of the present disclosure (where m=n=2).

FIG. 25 is a configuration diagram of a voltage generation circuit according to Example EX2E belonging to the second embodiment of the present disclosure.

FIG. 26 is a configuration diagram of the voltage generation circuit according to Example EX2E belonging to the second embodiment of the present disclosure (where m=n=2).

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Examples of embodiments of the present disclosure will be specifically described below with reference to the drawings. Throughout the referred drawings, the same parts are denoted by the same reference numerals, and duplicate explanation thereof will be omitted in principle. In the present disclosure, for the sake of simplification of description, by describing a symbol or a reference numeral that refers to information, a signal, a physical quantity, a functional part, a circuit, an element, a component, or the like, a name of the information, the signal, the physical quantity, the functional part, the circuit, the element, the components, or the like corresponding to the pertinent symbol or the reference numeral may be omitted or abbreviated.

First, some terms used in the description of the embodiments of the present disclosure will be described. Regarding any transistor configured as a FET (Field Effect Transistor) including a MOSFET, an on state refers to a state in which a drain and a source of the pertinent transistor are electrically connected, and an off state refers to a state in which the drain and the source of the pertinent transistor are electrically disconnected (cut-off). MOSFET is an abbreviation for “metal-oxide-semiconductor field-effect transistor.” Further, unless otherwise specified, a back gate of any MOSFET may be considered to be short-circuited to the source of the MOSFET.

Electrical characteristics of a MOSFET include a gate threshold voltage. For any transistor which is an N-channel enhancement type MOSFET, when a gate potential of the transistor is higher than a source potential of the transistor and a magnitude of a gate-source voltage of the transistor is equal to or larger than a gate threshold voltage of the transistor, the transistor is turned on, and otherwise, the transistor is turned off. For any transistor which is a P-channel enhancement type MOSFET, when the gate potential of the transistor is lower than the source potential of the transistor and the magnitude of the gate-source voltage of the transistor is equal to or larger than the gate threshold voltage of the transistor, the transistor is turned on, and otherwise, the transistor is turned off. The same applies to a depletion type MOSFET. However, while an enhancement type MOSFET has a positive gate threshold voltage, a depletion type MOSFET has a negative gate threshold voltage.

For any FET, a gate threshold voltage is defined as a gate-source voltage required to cause a predetermined magnitude of drain current to flow when a predetermined voltage is applied between the drain and source of the FET under a predetermined ambient temperature environment. In any transistor configured as a MOSFET, a gate-source voltage refers to a gate potential as viewed from a source potential. Hereinafter, an on state and an off state of any transistor may be simply referred to as on and off.

A connection between a plurality of parts forming a circuit, such as arbitrary circuit elements, wirings, and nodes, may be understood as referring to an electrical connection, unless otherwise specified.

### First Embodiment

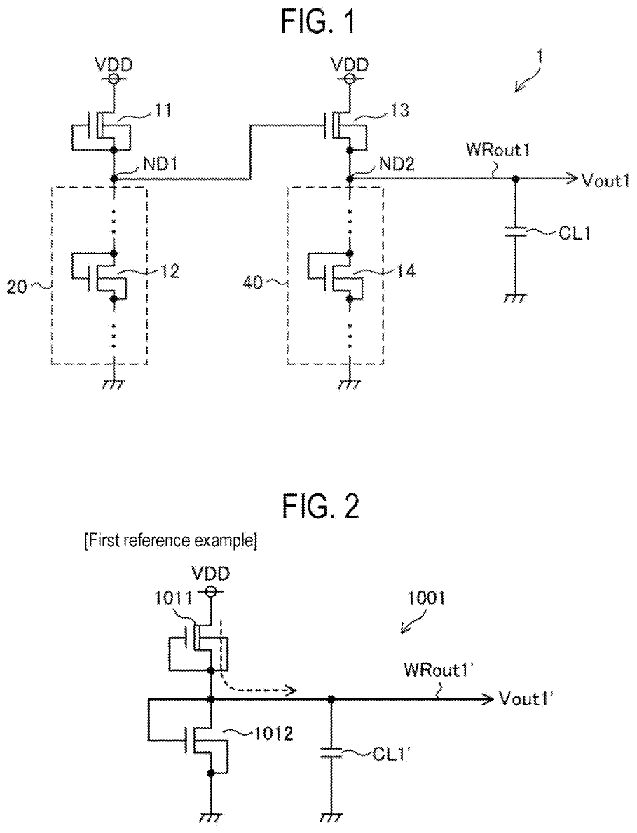

A first embodiment of the present disclosure will be described. FIG. 1 is a configuration diagram of a voltage generation circuit 1 according to the first embodiment. The voltage generation circuit 1 is a DC voltage source (reference voltage source) configured to generate a DC output voltage Vout1 from a DC power supply voltage VDD, and belongs to a linear regulator. The power supply voltage VDD has a positive DC voltage value. The voltage generation circuit 1 generates the output voltage Vout1 such that the output voltage Vout1 is stabilized at a predetermined target voltage Vtg1. The target voltage Vtg1 is a positive DC voltage lower than the power supply voltage VDD.

In the present embodiment and other embodiments of the present disclosure to be described later, a power supply end refers to a terminal to which the power supply voltage VDD is applied, and a ground end refers to a terminal to which a voltage of 0 V is applied. In the present embodiment and other embodiments of the present disclosure to be described below, the voltage of 0 V is also referred to as a ground voltage.

The voltage generation circuit 1 includes a transistor 11, a front-stage transistor circuit 20 including one or more transistors 12 (front-stage transistors), a transistor 13, and a rear-stage transistor circuit 40 including one or more transistors 14 (rear-stage transistors).

The transistors 11 and 13 are N-channel type and depletion type MOSFETs, respectively. Therefore, even in a case where a gate-source voltage of the transistor 11 is 0 V, a drain-source of the transistor 11 is in a conductive state, and at that time, in a case where a drain potential of the transistor 11 is higher than a source potential of the transistor 11, a drain current flows through the transistor 11. Similarly, even in a case where a gate-source voltage of the transistor 13 is 0 V, a drain-source of the transistor 13 is in a conductive state, and at that time, in a case where a drain potential of the transistor 13 is higher than a source potential of the transistor 13, a drain current flows through the transistor 13.

The transistors 12 and 14 are N-channel type and enhancement type MOSFETs, respectively. Therefore, in a case where a gate-source voltage of the transistor 12 is 0V, a drain-source of the transistor 12 is in a cut-off state, and at that time, even in a case where a drain potential of the transistor 12 is higher than a source potential of the transistor 12, no drain current flows through the transistor 12. Similarly, in a case where a gate-source voltage of the transistor 14 is 0 V, a drain-source of the transistor 14 is in a cut-off state, and at that time, even in a case where a drain potential of the transistor 14 is higher than a source potential of the transistor 14, no drain current flows through the transistor 14.

The drain of the transistor 11 is connected to the power supply end. A source, a gate, and a back gate of the transistor 11 are connected in common to a node ND1. A front-stage transistor circuit 20 is connected between the node ND1 and the ground end. The transistor 11 and the front-stage transistor circuit 20 generate a voltage lower than the power supply voltage VDD and higher than the ground voltage at the node ND1.

A drain of the transistor 13 is connected to the power supply end. A source and a back gate of the transistor 13 are connected in common to a node ND2. A gate of the transistor 13 is connected to the node ND1. The rear-stage transistor circuit 40 is connected between the node ND2 and the ground end. The transistor 13 and the rear-stage transistor circuit 40 generate a voltage lower than the power supply voltage VDD and higher than the ground voltage at the node ND2, as the output voltage Vout1.

The node ND2 is connected to an output wiring WRout1. Therefore, the output voltage Vout1 is applied to the output wiring WRout1. A load capacitance CL1 is a parasitic capacitance formed between the output wiring WRout1 and a wiring to which the ground voltage is applied (hereinafter referred to as a ground wiring). The load capacitance CL1 includes input capacitances of various load circuits (not shown) configured to receive the output voltage Vout1. In the various load circuits configured to receive the output voltage Vout1, the output voltage Vout1 may be used as a reference voltage.

When the voltage generation circuit 1 is started up, the output voltage Vout1 increases from 0 V toward the predetermined target voltage Vtg1. A period during which the output voltage Vout1 increases from 0 V toward the predetermined target voltage Vtg1 at the time of start-up of the voltage generation circuit 1 is hereinafter referred to as a start-up period.

In a state where the output voltage Vout1 is stabilized at the target voltage Vtg1, a bias current flows from the power supply end toward the ground terminal through the transistor 11 and the front-stage transistor circuit 20, and another bias current flows from the power supply end toward the ground terminal through the transistor 13 and the rear-stage transistor circuit 40. In a state where the output voltage Vout1 is stabilized at the target voltage Vtg1, a voltage corresponding to a gate threshold voltage of the transistor 12 is applied to the node ND1, and a voltage corresponding to a gate threshold voltage of the transistor 14 is applied to the node ND2.

The first embodiment includes the following Examples EX1A to EX1E. The matters described above in the first embodiment apply to the following Examples EX1A to EX1E unless otherwise specified and unless contradictory. However, in each Example, regarding matters that contradict the matters described above in the first embodiment, the description in each Example may take precedence. Further, unless contradictory, the matters described in any of Examples EX1A to EX1E may also be applied to any other Examples (that is, it is also possible to combine any two or more of plural Examples).

[First Reference Example]

Prior to description of Examples EX1A to EX1E, a configuration of a voltage generation circuit 1001 according to a first reference example will be described with reference to FIG. 2. The voltage generation circuit 1001 includes a series circuit of transistors 1011 and 1012 provided between a power supply end and a ground end. The transistor 1011 is an N-channel depletion type MOSFET. The transistor 1012 is an N-channel enhancement type MOSFET. The transistor 1011 is provided on the side of the power supply end, and the transistor 1012 is provided on the side of the ground terminal.

A drain of the transistor 1011 is connected to the power supply end, and a gate, a source, and a back gate of the transistor 1011 are connected in common to an output wiring WRout1′. A gate and a drain of the transistor 1012 are connected to the output wiring WRout1′, and a source and a back gate of the transistor 1012 are connected to the ground terminal.

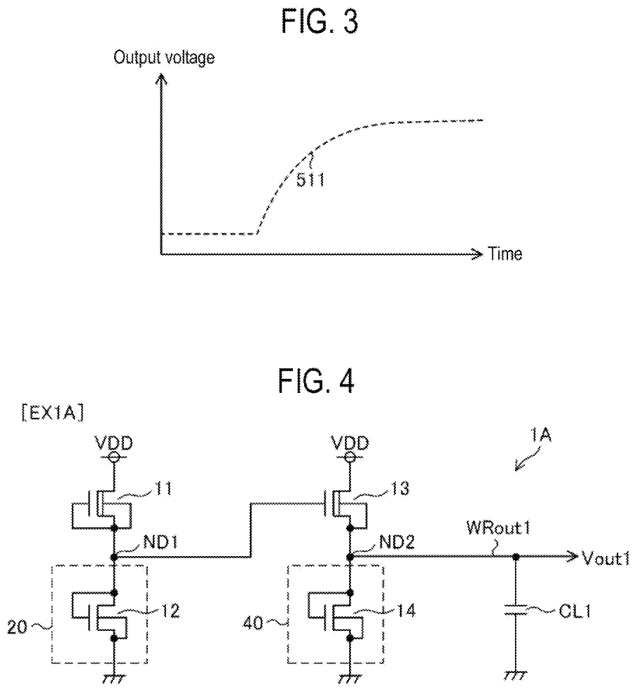

When an output voltage Vout1′ is still around 0 V, a current flows from the power supply end toward the output wiring WRout1′ through the transistor 1011, and the output voltage Vout1′ increases. In the process of increasing the output voltage Vout1′, a load capacitance CL1′ is driven by a drain current of the transistor 1011. However, in the voltage generation circuit 1001, regardless of a level of the output voltage Vout1′, since the gate-source voltage of the transistor 1011 is small (fixed at 0 V), the drive current of the load capacitance CL1′ is also small. As a result, as shown in FIG. 3, it takes a long time for the output voltage Vout1′ to reach a desired stabilized voltage when the voltage generation circuit 1001 is started up. In FIG. 3, a broken-line waveform 511 represents a waveform of the output voltage Vout1′ when the voltage generation circuit 1001 is started up.

### Example EX1A

Example EX1A will be described. FIG. 4 is a configuration diagram of a voltage generation circuit 1A corresponding to the voltage generation circuit 1, according to Example EX1A. In the voltage generation circuit 1A, only one transistor 12 is provided in the front-stage transistor circuit 20, and only one transistor 14 is provided in the rear-stage transistor circuit 40.

In the voltage generation circuit 1A, a drain of the single transistor 12 is connected to a node ND1, and a drain of the single transistor 14 is connected to a node ND2. In the voltage generation circuit 1A, a source and a back gate of the single transistor 12 and a source and a back gate of the single transistor 14 are connected to the ground end. In the voltage generation circuit 1A, a gate of the single transistor 12 is connected to the node ND1, and a gate of the single transistor 14 is connected to the node ND2.

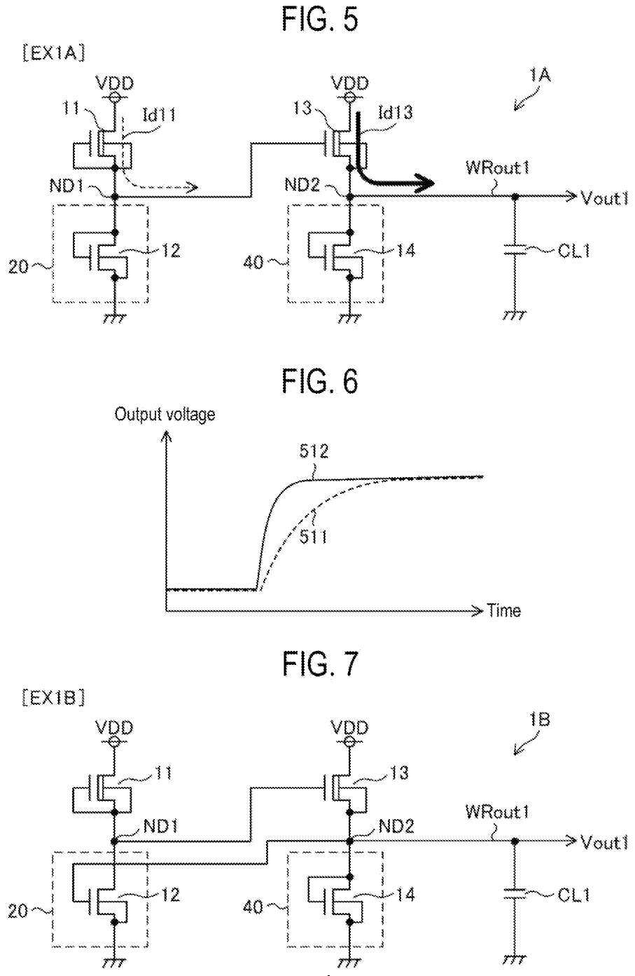

A behavior of a start-up period in the voltage generation circuit 1A will be described with reference to FIG. 5. During the start-up period, a drain current Id11 flows through the transistor 11, and the drain current Id11 increases a potential of the node ND1. Since a gate-source voltage of the transistor 11 is small (0 V), the drain current Id11 of the transistor 11 is not large, similar to the drain current of the transistor 1011 according to the first reference example. However, since a parasitic capacitance between the node ND1 and the ground wiring is sufficiently smaller than the load capacitance CL1, the potential of the node ND1 (therefore, a gate potential of the transistor 13) quickly rises during the start-up period.

In addition, during the start-up period, in a state where the output voltage Vout1 is lower than the target voltage Vtg1 (particularly in a state where the output voltage Vout1 is close to 0 V, for example), a gate-source voltage of the transistor 13 becomes significantly larger than 0 V. As a result, a drain current Id13 of the transistor 13 becomes larger than that when the gate-source voltage of the transistor 13 is 0 V. Therefore, during the start-up period, a drive current of the load capacitance CL1 becomes larger than that in the first reference example, and the output voltage Vout1 rises to the target voltage Vtg1 in a short time (that is, the time required for start-up is shortened).

FIG. 6 shows waveforms of output voltages in the first reference example and Example EX1A. A broken-line waveform 511 is similar to that shown in FIG. 3. A solid-line waveform 512 represents a waveform of the output voltage Vout1 when the voltage generation circuit 1A is started up.

### Example EX1B

Example EX1B will be described. FIG. 7 is a configuration diagram of a voltage generation circuit 1B corresponding to the voltage generation circuit 1, according to Example EX1B. In the voltage generation circuit 1B, only one transistor 12 is provided in the front-stage transistor circuit 20, and only one transistor 14 is provided in the rear-stage transistor circuit 40. In the voltage generation circuit 1B, a gate of the single transistor 12 is connected to the node ND2 without being connected to the node ND1. Except for this point, the voltage generation circuit 1B of FIG. 7 has the same configuration as the voltage generation circuit 1A of FIG. 4.

In the voltage generation circuit 1B of FIG. 7, the transistor 12 is turned off when the output voltage Vout1 is equal to or lower than a gate threshold voltage of the transistor 12, and therefore, a drain current of the transistor 11 entirely contributes to raising a gate potential of the transistor 13. Therefore, as compared with the voltage generation circuit 1A, in the voltage generation circuit 1B, the gate potential of the transistor 13 rises steeply at the time of start-up, and in conjunction with this, the output voltage Vout1 quickly rises (that is, the time required for start-up is shortened).

### Example EX1C

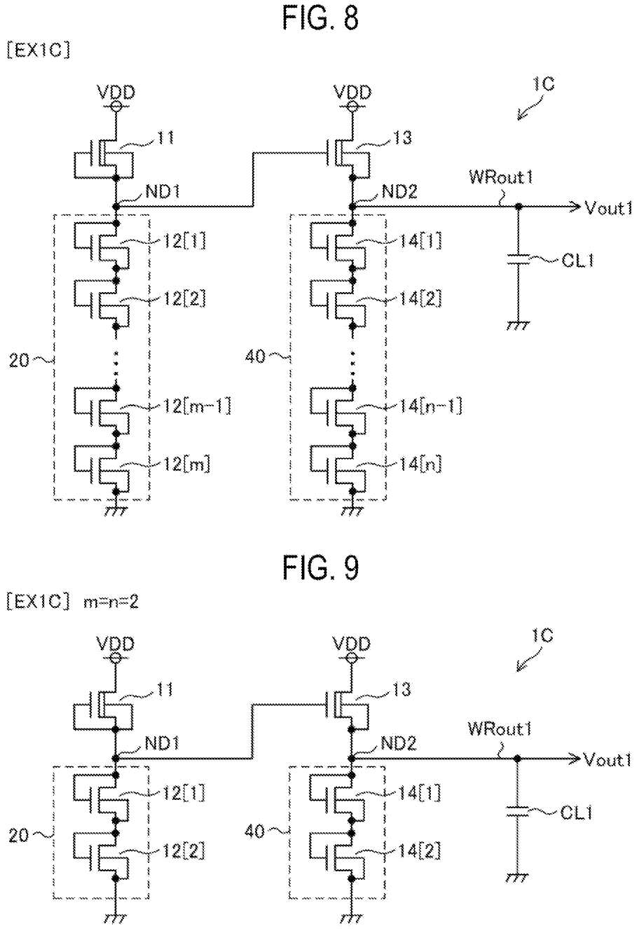

Example EX1C will be described. FIG. 8 is a configuration diagram of a voltage generation circuit 1C corresponding to the voltage generation circuit 1, according to Example EX1C. The voltage generation circuit 1C of FIG. 8 corresponds to the voltage generation circuit 1A in FIG. 4, with a plurality of transistors 12 constituting the front-stage transistor circuit 20 and a plurality of transistors 14 constituting the rear-stage transistor circuit 40. The voltage generation circuit 1C may also obtain the same effects as the voltage generation circuit 1A, and the output voltage Vout1 may be increased as necessary.

Specifically, in the voltage generation circuit 1C, the front-stage transistor circuit 20 is provided with m transistors 12, and the rear-stage transistor circuit 40 is provided with n transistors 14. Herein, m and n each represent an integer of 2 or more. It may be “m=n,” “m>n” or “m<n.” FIG. 9 shows a configuration of the voltage generation circuit 1C when “m=n=2.”

The m transistors 12 in the front-stage transistor circuit 20 are referred to as transistors 12[1] to 12[m]. The transistors 12[1] to 12[m] are connected in series with each other between the node ND1 and the ground end. The n transistors 14 in the rear-stage transistor circuit 40 are referred to as transistors 14[1] to 14[n]. The transistors 14[1] to 14[n] are connected in series with each other between the node ND2 and the ground end.

In the front-stage transistor circuit 20, the transistors 12[1] to 12[m] are provided in this order from the node ND1 toward the ground end. Therefore, a transistor 12[i] and a transistor 12[i+1] are adjacent to each other. In the rear-stage transistor circuit 40, the transistors 14[1] to 14[n] are provided in this order from the node ND2 toward the ground end. Therefore, a transistor 14[i] and a transistor 14[i+1] are adjacent to each other. Herein, i represents any integer.

The transistors 12[1] to 12[m] each include a source and a back gate that are short-circuited to each other. That is, for each integer i that satisfies “1≤i≤m,” the source and the back gate of the transistor 12[i] are short-circuited to each other. In the transistors 12[1] to 12[m], out of the two transistors 12[i] and 12[i+1] that are adjacent to each other, a drain of one transistor 12[i+1] is connected to a source of the other transistor 12[i]. A drain of the transistor 12[1] is connected to the node ND1. A source of the transistor 12[m] is connected to the ground end.

In the voltage generation circuit 1C, the transistors 12[1] to 12[m] each include a gate and a drain that are short-circuited to each other. That is, for each integer i that satisfies “1≤ism,” the gate and drain of the transistor 12[i] are short-circuited together.

The transistors 14[1] to 14[n] each include a source and a back gate that are short-circuited to each other. That is, for each integer i that satisfies “I≤i≤n,” the source and the back gate of the transistor 14[i] are short-circuited to each other. The transistors 14[1] to 14[n] each include a drain and a gate that are short-circuited to each other. That is, for each integer i that satisfies “1≤i≤n,” the drain and the gate of the transistor 14[i] are short-circuited to each other. In the transistors 14[1] to 14[n], out of the two transistors 14[i] and 14[i+1] that are adjacent to each other, the drain of one transistor 14[i+1] is connected to the source of the other transistor 14[i]. The drain of the transistor 14[1] is connected to the node ND2. The source of the transistor 14[n] is connected to the ground end.

Therefore, in a case where “m=2” in the voltage generation circuit 1C (see FIG. 9), the drain and the gate of the transistor 12[1] are connected to the node ND1, the source and the back gate of the transistor 12[1] are connected to the drain and the gate of the transistor 12[2], and the source and the back gate of the transistor 12[2] are connected to the ground end. In a case where “n=2” in the voltage generation circuit 1C (see FIG. 9), the drain and the gate of the transistor 14[1] are connected to the node ND2, the source and the back gate of the transistor 14[1] are connected to the drain and the gate of the transistor 14[2], and the source and the back gate of the transistor 14[2] are connected to the ground end.

### Example EX1D

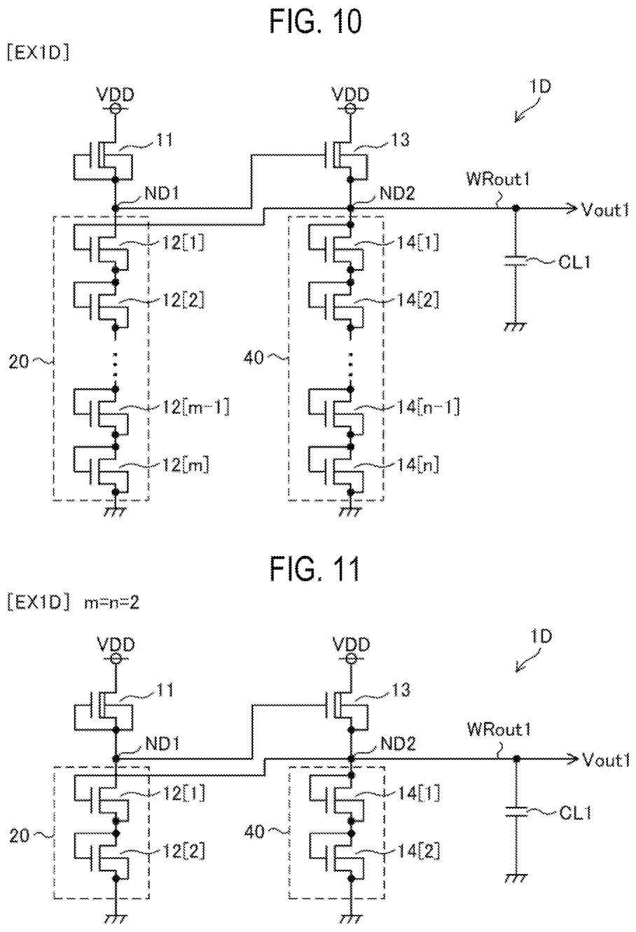

Example EX1D will be described. FIG. 10 is a configuration diagram of a voltage generation circuit 1D corresponding to the voltage generation circuit 1, according to Example EX1D. Similarly to modifying the voltage generation circuit 1A (see FIG. 4) according to Example EX1A to the voltage generation circuit 1B (see FIG. 7) according to Example EX1B, the voltage generation circuit 1D (see FIG. 10) is a voltage generation circuit obtained by modifying the voltage generation circuit 1C (see FIG. 8) according to Example EX1C.

That is, in the voltage generation circuit 1D, similarly to the voltage generation circuit 1C, the front-stage transistor circuit 20 is provided with m transistors 12, and the rear-stage transistor circuit 40 is provided with n transistors 14. However, in the voltage generation circuit 1D, the gate of the transistor 12[1] is connected to the node ND2 without being connected to the node ND1. Except for this point, the voltage generation circuit 1D of FIG. 10 has the same configuration as the voltage generation circuit 1C of FIG. 8.

Therefore, in the voltage generation circuit 1D, the transistors 12[2] to 12[m] each include a gate and a drain that are short-circuited to each other. That is, for each integer i that satisfies “2≤i≤m,” the gate and the drain of the transistor 12[i] are short-circuited to each other.

In the voltage generation circuit 1D of FIG. 10, in a state where the output voltage Vout1 is equal to or lower than a sum of the gate threshold voltages of the transistors 12[1] to 12[m], no current flows through the front-stage transistor circuit 20, and therefore, a drain current of the transistor 11 entirely contributes to raising a gate potential of the transistor 13. Therefore, as compared with the voltage generation circuit 1C, in the voltage generation circuit 1D, the gate potential of the transistor 13 rises steeply at the time of start-up, and in conjunction with this, the output voltage Vout1 quickly rises toward the target voltage Vtg1 (that is, the time required for start-up is shortened).

FIG. 11 shows a configuration of the voltage generation circuit 1D when “m=n=2.” In a case where “m=2” in the voltage generation circuit 1D, the drain of the transistor 12[1] is connected to the node ND1, the gate of the transistor 12[1] is connected to the node ND2 without being connected to the node ND1, the source and the back gate of the transistor 12[1] are connected to the drain and the gate of the transistor 12[2], and the source and the back gate of the transistor 12[2] are connected to the ground end. In a case where “n=2” in the voltage generation circuit 1D, the drain and the gate of the transistor 14[1] are connected to the node ND2, the source and back gate of the transistor 14[1] are connected to the drain and the gate of the transistor 14[2], and the source and the back gate of the transistor 14[2] are connected to the ground end.

### Example EX1E

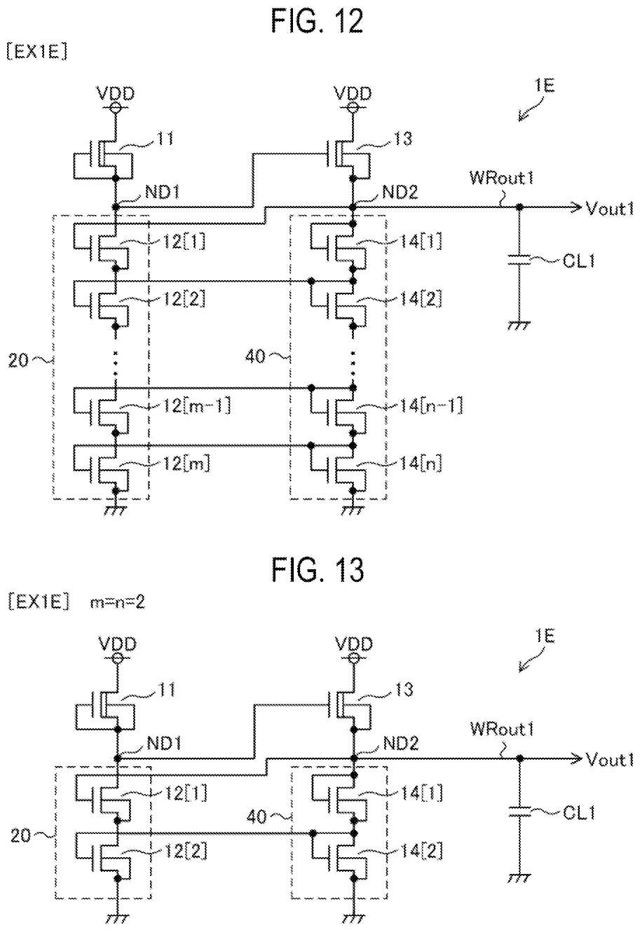

Example EX1E will be described. The following modification MD1E may be applied to the voltage generation circuit 1D according to Example EX1D. FIG. 12 shows a configuration of a voltage generation circuit 1E obtained by applying the modification MD1E to the voltage generation circuit 1D. The voltage generation circuit 1E according to Example EX1E corresponds to the voltage generation circuit 1.

In the modification MD1E, for each integer i that satisfies “2≤i≤N” after setting “m=n=N,” the gate of the transistor 12[i] is connected to the gate and the drain of the transistor 14[i] without being connected to the drain of the transistor 12[i] and the source and the back gate of the transistor 12[i-1]. N is any integer of 2 or more. Except for the modification MD1E, the voltage generation circuit 1E of FIG. 12 has the same configuration as the voltage generation circuit 1D of FIG. 10. Therefore, similarly to the voltage generation circuit 1D, in the voltage generation circuit 1E, the gate of the transistor 12[1] is connected to the node ND2 without being connected to the node ND1. The voltage generation circuit 1E may also provide the same effects as the voltage generation circuit 1D.

FIG. 13 shows a configuration of the voltage generation circuit 1E when “m=n=N=2.” In a case where “m=n=N=2” in the voltage generation circuit 1E, the drain of the transistor 12[1] is connected to the node ND1, the gate of the transistor 12[1] is connected to the node ND2 without being connected to the node ND1, the source and the back gate of the transistor 12[1] are connected only to the drain of the transistor 12[2], the gate of the transistor 12[2] is connected to the gate of the transistor 14[2] without being connected to the drain of the transistor 12[2], and the source and back gate of the transistor 12[2] are connected to the ground end. In a case where “m=n=N=2” in the voltage generation circuit 1E, the drain and the gate of the transistor 14[1] are connected to the node ND2, the source and the back gate of the transistor 14[1] are connected to the drain and the gate of the transistor 14[2], and the source and the back gate of the transistor 14[2] are connected to the ground end.

### Second Embodiment

A second embodiment of the present disclosure will be described. The voltage generation circuit 1 according to the first embodiment may be configured with a P-channel MOSFET. However, in this case, it is necessary to switch a relationship between the ground end and the power supply end. In the second embodiment, a voltage generation circuit formed by using a P-channel MOSFET will be described.

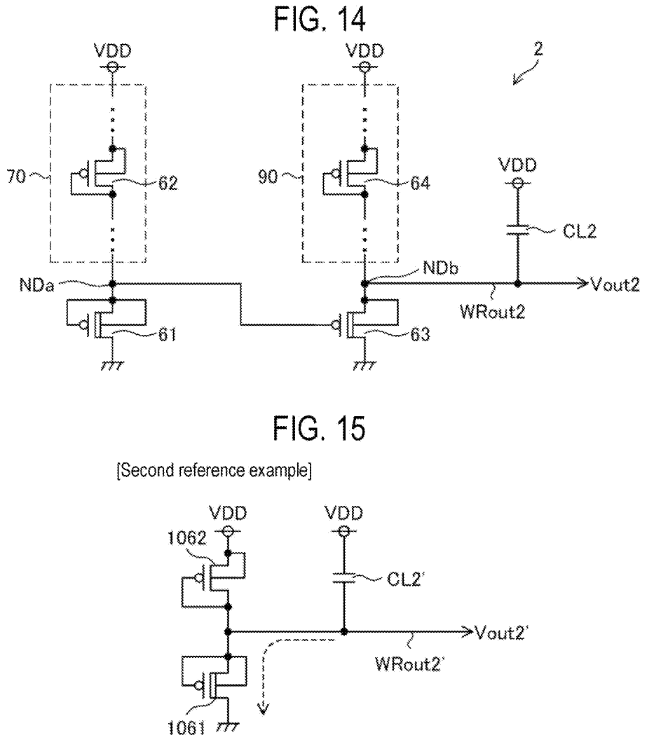

FIG. 14 is a configuration diagram of a voltage generation circuit 2 according to the second embodiment. The voltage generation circuit 2 is a DC voltage source (reference voltage source) configured to generate a DC output voltage Vout2 from a DC power supply voltage VDD, and belongs to a linear regulator. The power supply voltage VDD has a positive DC voltage value. The voltage generation circuit 2 generates the output voltage Vout2 such that the output voltage Vout2 is stabilized at a predetermined target voltage Vtg2. The target voltage Vtg2 is a positive DC voltage lower than the power supply voltage VDD.

The output voltage Vout1 in the first embodiment is 0 V before the voltage generation circuit 1 is started up, and as the voltage generation circuit 1 is started up, the output voltage Vout1 increases from 0 V toward the predetermined positive target voltage Vtg1. Thereafter, the output voltage Vout1 is stabilized at the target voltage Vtg1. In contrast, the output voltage Vout2 in the second embodiment has a value of the power supply voltage VDD before the voltage generation circuit 2 is started up, and as the voltage generation circuit 2 is started up, the output voltage Vout2 decreases from the power supply voltage VDD toward the predetermined positive target voltage Vtg2, and then is stabilized at the target voltage Vtg2.

The voltage generation circuit 2 includes a transistor 61, a front-stage transistor circuit 70 including one or more transistors 62 (front-stage transistors), a transistor 63, and a rear-stage transistor circuit 90 including one or more transistors 64 (rear-stage transistors).

The transistors 61 and 63 are P-channel type and depletion type MOSFETs, respectively. Therefore, even in a case where a gate-source voltage of the transistor 61 is 0 V, a drain-source of the transistor 61 is in a conductive state, and at this time, when a source potential of the transistor 61 is higher than a drain potential of the transistor 61, a drain current flows through the transistor 61. Similarly, even in a case where a gate-source voltage of the transistor 63 is 0 V, a drain-source of the transistor 63 is in a conductive state, and at this time, when a source potential of the transistor 63 is higher than a drain potential of the transistor 63, a drain current flows through the transistor 63.

The transistors 62 and 64 are P-channel type and enhancement type MOSFETs, respectively. Therefore, in a case where a gate-source voltage of the transistor 62 is 0 V, a drain-source of the transistor 62 is in a cut-off state, and at that time, even in a case where a source potential of the transistor 62 is higher than a drain potential of the transistor 62, no drain current flows through the transistor 62. Similarly, in a case where a gate-source voltage of the transistor 64 is 0 V, a drain-source of the transistor 64 is in a cut-off state, and at that time, even in a case where a source potential of the transistor 64 is higher than a drain potential of the transistor 64, no drain current flows through the transistor 64.

A drain of the transistor 61 is connected to the ground end. A source, a gate, and a back gate of the transistor 61 are connected in common to a node NDa. The front-stage transistor circuit 70 is connected between the node NDa and the power supply end. The transistor 61 and the front-stage transistor circuit 70 generate a voltage lower than the power supply voltage VDD and higher than the ground voltage at the node NDa.

A drain of the transistor 63 is connected to the ground end. A source and a back gate of the transistor 63 are connected in common to a node NDb. The gate of the transistor 63 is connected to the node NDa. The rear-stage transistor circuit 90 is connected between the node NDb and the power supply end. The transistor 63 and the rear-stage transistor circuit 90 generate a voltage lower than the power supply voltage VDD and higher than the ground voltage at the node NDb, as the output voltage Vout2.

The node NDb is connected to an output wiring WRout2. Therefore, the output voltage Vout2 is applied to the output wiring WRout2. A load capacitance CL2 is a parasitic capacitance formed between the output wiring WRout2 and a wiring to which the power supply voltage VDD is applied (hereinafter, referred to as a power supply wiring). The load capacitance CL2 includes input capacitances of various load circuits (not shown) configured to receive the output voltage Vout2. In the various load circuits configured to receive the output voltage Vout2, the output voltage Vout2 may be used as a reference voltage.

When the voltage generation circuit 2 is started up, the output voltage Vout2 decreases from the power supply voltage VDD toward the predetermined target voltage Vtg2. A start-up period in the second embodiment of the present disclosure is a period during which the output voltage Vout2 decreases from the power supply voltage VDD toward the predetermined target voltage Vtg2 when the voltage generation circuit 2 is started up.

In a state where the output voltage Vout2 is stabilized at the target voltage Vtg2, a bias current flows from the power supply end toward the ground end through the front-stage transistor circuit 70 and the transistor 61, and another bias current flows from the power supply end toward the ground end through the rear-stage transistor circuit 90 and the transistor 63. In the state where the output voltage Vout2 is stabilized at the target voltage Vtg2, a voltage corresponding to a gate threshold voltage of the transistor 62 is applied to the node NDa, and a voltage corresponding to a gate threshold voltage of the transistor 64 is applied to the node NDb.

The second embodiment includes the following Examples EX2A to EX2E. The matters described above in the second embodiment apply to the following Examples EX2A to EX2E unless otherwise specified and unless contradictory. However, in each Example, regarding matters that contradict the matters described above in the second embodiment, the description in each Example may take precedence. Further, unless contradictory, the matters described in any of Examples EX2A to EX2E may also be applied to any other Examples (that is, it is also possible to combine any two or more of plural Examples).

### Second Reference Example

Prior to describing Examples EX2A to EX2E, a configuration of a voltage generation circuit 1002 according to a second reference example will be described with reference to FIG. 15. The voltage generation circuit 1002 includes a series circuit of transistors 1061 and 1062 provided between a ground end and a power supply end. The transistor 1061 is a P-channel depletion type MOSFET. The transistor 1062 is a P-channel enhancement type MOSFET. The transistor 1061 is provided on the side of the ground end, and the transistor 1062 is provided on the side of the power supply end.

A drain of the transistor 1061 is connected to the ground end, and a gate, a source, and a back gate of the transistor 1061 are connected in common to an output wiring WRout2′. A gate and a drain of the transistor 1062 are connected to the output wiring WRout2′, and a source and a back gate of the transistor 1062 are connected to the power supply end.

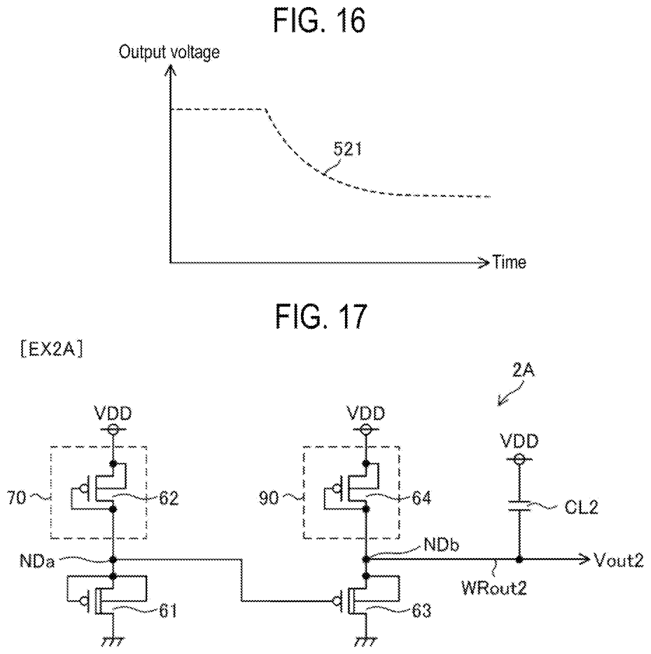

When an output voltage Vout2′ is still around the power supply voltage VDD, a current flows from the output wiring WRout2′ through the transistor 1061, and the output voltage Vout2′ decreases. In the process of decreasing the output voltage Vout2′, a load capacitance CL2′ is driven by the drain current of the transistor 1061. However, in the voltage generation circuit 1002, regardless of a level of the output voltage Vout2′, since the gate-source voltage of the transistor 1061 is small (fixed to 0 V), the drive current of the load capacitance CL2′ is also small. As a result, as shown in FIG. 16, it takes a long time for the output voltage Vout2′ to reach a desired stabilized voltage when the voltage generation circuit 1002 is started up. In FIG. 16, a broken-line waveform 521 represents a waveform of the output voltage Vout2′ when the voltage generation circuit 1002 is started up.

### Example EX2A

Example EX2A will be described. FIG. 17 is a configuration diagram of a voltage generation circuit 2A corresponding to the voltage generation circuit 2, according to Example EX2A. In the voltage generation circuit 2A, only one transistor 62 is provided in the front-stage transistor circuit 70, and only one transistor 64 is provided in the rear-stage transistor circuit 90.

In the voltage generation circuit 2A, a drain of the single transistor 62 is connected to the node NDa, and a drain of the single transistor 64 is connected to the node NDb. In the voltage generation circuit 2A, a source and a back gate of the single transistor 62 and a source and a back gate of the single transistor 64 are connected to the power supply end. In the voltage generation circuit 2A, a gate of the single transistor 62 is connected to the node NDa, and a gate of the single transistor 64 is connected to the node NDb.

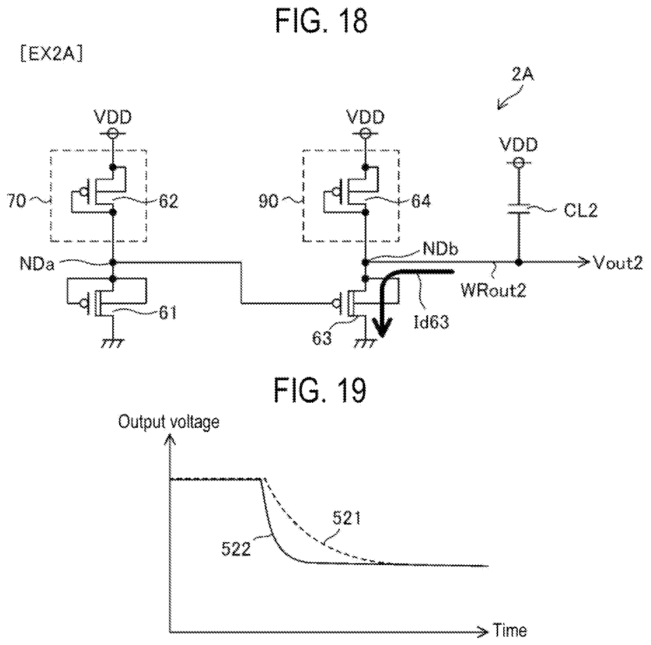

A behavior of a start-up period in the voltage generation circuit 2A will be described with reference to FIG. 18. It is assumed that a voltage across the load capacitance CL2 is 0 V immediately before the start-up of the voltage generation circuit 2A. During the start-up period, in a state where the output voltage Vout2 is close to the power supply voltage VDD, the gate-source voltage of the transistor 63 becomes significantly larger than 0 V. As a result, a drain current Id63 of the transistor 63 becomes larger than that when the gate-source voltage of the transistor 63 is 0 V. Therefore, during the start-up period, the drive current of the load capacitance CL2 becomes larger than that in the second reference example, and the output voltage Vout2 decreases to the target voltage Vtg2 in a short time (that is, the time required for start-up is shortened).

FIG. 19 shows waveforms of output voltages in the second reference example and Example EX2A. A broken-line waveform 521 is similar to that shown in FIG. 16. A solid-line waveform 522 represents a waveform of the output voltage Vout2 when the voltage generation circuit 2A is started up.

### Example EX2B

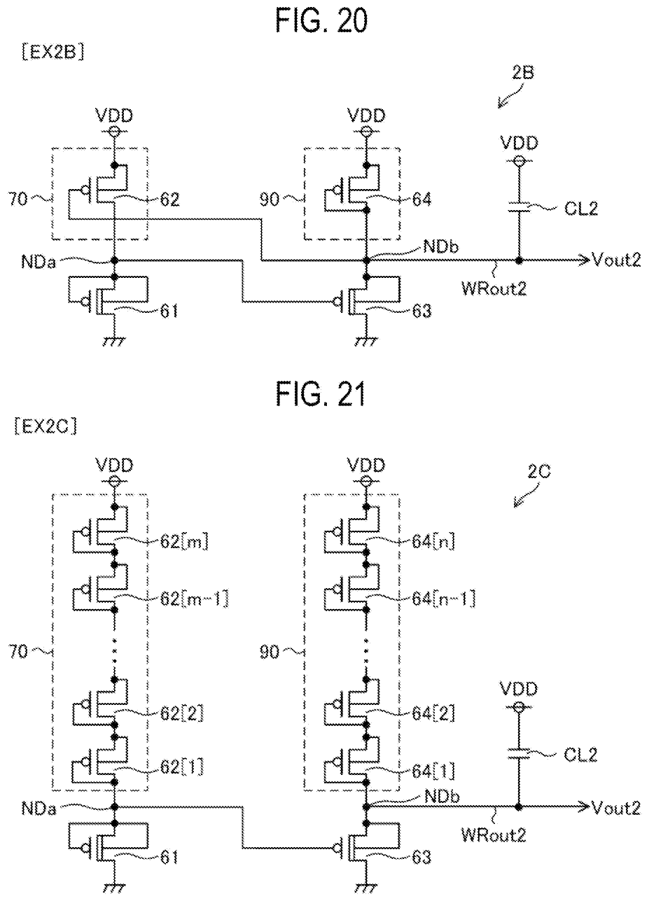

Example EX2B will be described. FIG. 20 is a configuration diagram of a voltage generation circuit 2B corresponding to the voltage generation circuit 2, according to Example EX2B. In the voltage generation circuit 2B, only one transistor 62 is provided in the front-stage transistor circuit 70, and only one transistor 64 is provided in the rear-stage transistor circuit 90. In the voltage generation circuit 2B, a gate of the single transistor 62 is connected to the node NDb without being connected to the node NDa. Except for this point, the voltage generation circuit 2B of FIG. 20 has the same configuration as the voltage generation circuit 2A of FIG. 17.

In the voltage generation circuit 2B of FIG. 20, the transistor 62 is off when the output voltage Vout2 is close to the power supply voltage VDD, and therefore, a gate potential of the transistor 63 becomes approximately 0 V by the transistor 61. Therefore, as compared with the voltage generation circuit 2A, a drain current of the transistor 63 during the start-up period becomes larger, and in conjunction with this, the output voltage Vout2 quickly decreases toward the target voltage Vtg2 (that is, the time required for start-up is shortened).

### Example EX2C

Example EX2C will be described. FIG. 21 is a configuration diagram of a voltage generation circuit 2C corresponding to the voltage generation circuit 2, according to Example EX2C. The voltage generation circuit 2C in FIG. 21 corresponds to the voltage generation circuit 2A in FIG. 17, with a plurality of transistors 62 constituting the front-stage transistor circuit 70 and a plurality of transistors 64 constituting the rear-stage transistor circuit 90. The voltage generation circuit 2C may also provide the same effects as the voltage generation circuit 2A, and a difference between the power supply voltage VDD and the output voltage Vout2 (in other words, a difference between the power supply voltage VDD and the target voltage Vtg2) may be increased as necessary.

Specifically, in the voltage generation circuit 2C, the front-stage transistor circuit 70 is provided with m transistors 62, and the rear-stage transistor circuit 90 is provided with n transistors 64. Herein, m and n each refer to an integer of 2 or more. It may be “m=n,” “m>n” or “m<n.” FIG. 22 shows a configuration of the voltage generation circuit 2C when “m=n=2.”

The m transistors 62 in the front-stage transistor circuit 70 are referred to as transistors 62[1] to 62[m]. The transistors 62[1] to 62[m] are connected in series with each other between the node NDa and the power supply end. The n transistors 64 in the rear-stage transistor circuit 90 are referred to as transistors 64[1] to 64[n]. The transistors 64[1] to 64[n] are connected in series with each other between the node NDb and the power supply end.

In the front-stage transistor circuit 70, the transistors 62[1] to 62[m] are provided in this order from the node NDa toward the power supply end. Therefore, a transistor 62[i] and a transistor 62[i+1] are adjacent to each other. In the rear-stage transistor circuit 90, the transistors 64[1] to 64[n] are provided in this order from the node NDb toward the power supply end. Therefore, a transistor 64[i] and a transistor 64[i+1] are adjacent to each other. Herein, i represents any integer.

The transistors 62[1] to 62[m] each include a source and a back gate that are short-circuited to each other. That is, for each integer i that satisfies “1≤i≤m,” a source and a back gate of the transistor 62[i] are short-circuited to each other. In the transistors 62[1] to 62[m], out of the two transistors 62[i] and 62[i+1] that are adjacent to each other, a drain of one transistor 62[i+1] is connected to a source of the other transistor 62[i]. A drain of the transistor 62[1] is connected to the node NDa. A source of the transistor 62[m] is connected to the power supply end.

In the voltage generation circuit 2C, the transistors 62[1] to 62[m] each include a gate and a drain that are short-circuited to each other. That is, for each integer i that satisfies “1≤i≤m,” a gate and a drain of the transistor 62[i] are short-circuited to each other.

The transistors 64[1] to 64[n] each include a source and a back gate that are short-circuited to each other. That is, for each integer i that satisfies “1≤i≤n,” a source and a back gate of the transistor 64[i] are short-circuited together. The transistors 64[1] to 64[n] each include a drain and a gate that are short-circuited to each other. That is, for each integer i that satisfies “1≤m,” a drain and a gate of the transistor 64[i] are short-circuited to each other. In the transistors 64[1] to 64[n], out of the two transistors 64[i] and 64[i+1] that are adjacent to each other, a drain of one transistor 64[i+1] is connected to the source of the other transistor 64[i]. A drain of the transistor 64[1] is connected to the node NDb. A source of the transistor 64[n] is connected to the power supply end.

Therefore, in a case where “m=2” in the voltage generation circuit 2C (see FIG. 22), the drain and a gate of the transistor 62[1] are connected to the node NDa, a source and a back gate of the transistor 62[1] are connected to a drain and a gate of the transistor 62[2], and a source and a back gate of the transistor 62[2] are connected to the power supply end. In a case where “n=2” in the voltage generation circuit 2C (see FIG. 22), the drain and a gate of the transistor 64[1] are connected to the node NDb, a source and a back gate of the transistor 64[1] are connected to a drain and a gate of the transistor 64[2], and a source and a back gate of the transistor 64[2] are connected to the power supply end.

### Example EX2D

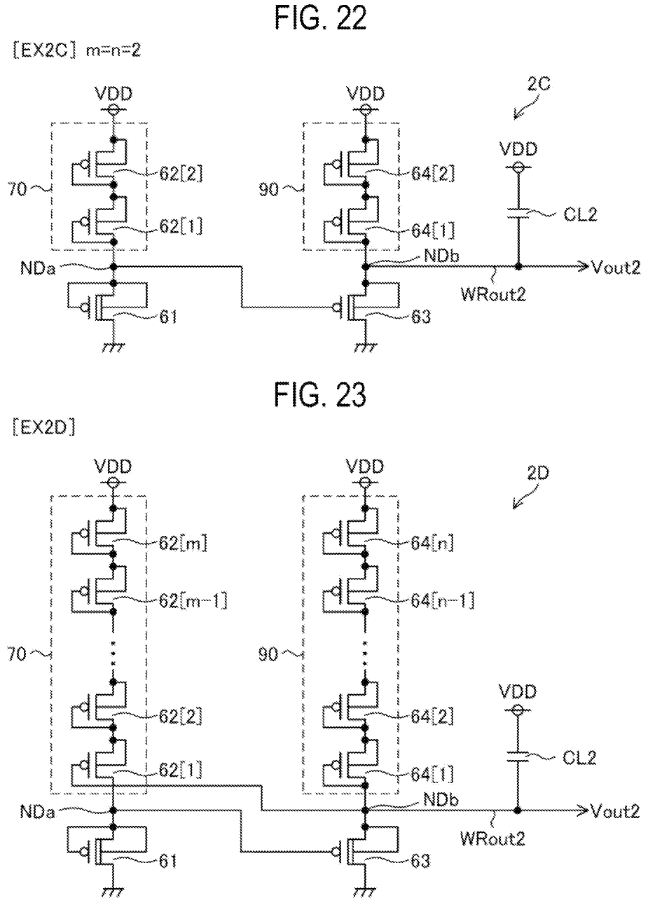

Example EX2D will be described. FIG. 23 is a configuration diagram of a voltage generation circuit 2D corresponding to the voltage generation circuit 2, according to Example EX2D. Similarly to modifying the voltage generation circuit 2A (see FIG. 17) according to Example EX2A to the voltage generation circuit 2B (see FIG. 20) according to Example EX2B, the voltage generation circuit 2D (see FIG. 23) is a voltage generation circuit obtained by modifying the voltage generation circuit 2C (see FIG. 21) according to Example EX2C.

That is, in the voltage generation circuit 2D, similarly to the voltage generation circuit 2C, the front-stage transistor circuit 70 is provided with m transistors 62, and the rear-stage transistor circuit 90 is provided with n transistors 64. However, in the voltage generation circuit 2D, a gate of the transistor 62[1] is connected to the node NDb without being connected to the node NDa. Except for this point, the voltage generation circuit 2D of FIG. 23 has the same configuration as the voltage generation circuit 2C of FIG. 21.

Therefore, in the voltage generation circuit 2D, the transistors 62[2] to 62[m] each include a gate and a drain that are short-circuited to each other. That is, for each integer i that satisfies “2≤ism,” a gate and a drain of the transistor 62[i] are short-circuited to each other.

In the voltage generation circuit 2D of FIG. 23, in a state where a difference voltage (VDD-Vout2) is equal to or lower than a sum of gate threshold voltages of the transistors 62[1] to 62[m], no current flows through the front-stage transistor circuit 70, and therefore, a gate potential of the transistor 63 is maintained at approximately 0 V by the transistor 61. Therefore, as compared with the voltage generation circuit 2C, in the voltage generation circuit 2D, the gate potential of the transistor 63 is easily kept low at the time of start-up, and therefore, the output voltage Vout2 quickly decreases toward the target voltage Vtg2 (that is, the time required for start-up is shortened).

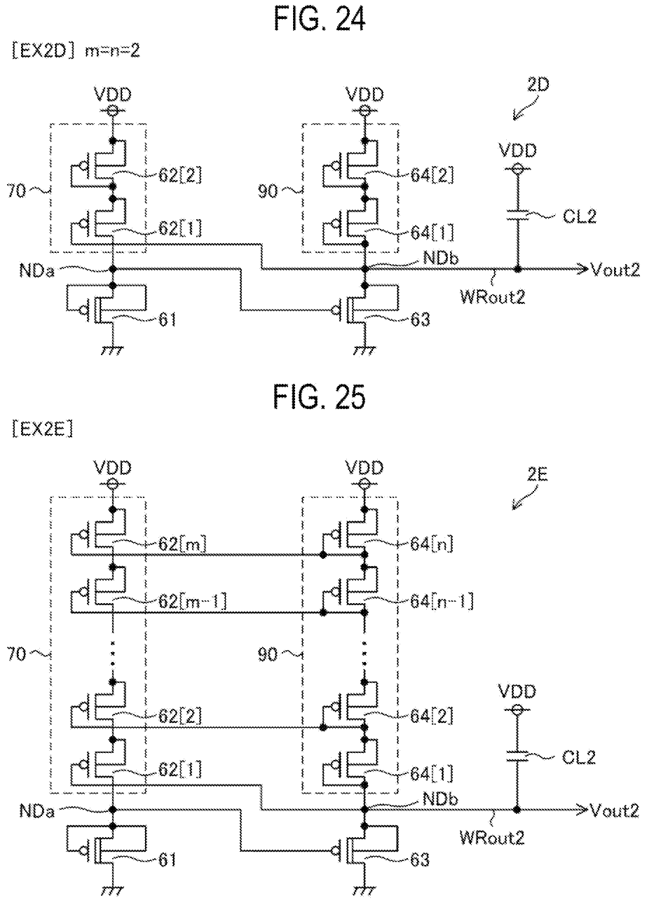

FIG. 24 shows a configuration of the voltage generation circuit 2D when “m=n=2.” In a case where “m=2” in the voltage generation circuit 2D, a drain of the transistor 62[1] is connected to the node NDa, a gate of the transistor 62[1] is connected to the node NDb without being connected to the node NDa, a source and a back gate of the transistor 62[1] are connected to a drain and a gate of the transistor 62[2], and a source and a back gate of the transistor 62[2] are connected to the power supply end. In a case where “n=2” in the voltage generation circuit 2D, a drain and a gate of the transistor 64[1] are connected to the node NDb, a source and a back gate of the transistor 64[1] are connected to a drain and a gate of the transistor 64[2], and a source and a back gate of the transistor 64[2] are connected to the power supply end.

### Example EX2E

Example EX2E will be described. The following modification MD2E may be applied to the voltage generation circuit 2D according to Example EX2D. FIG. 25 shows a configuration of a voltage generation circuit 2E obtained by applying the modification MD2E to the voltage generation circuit 2D. The voltage generation circuit 2E according to Example EX2E corresponds to the voltage generation circuit 2.

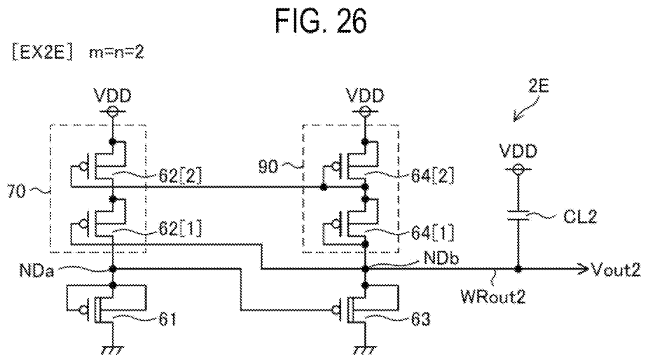

In the modification MD2E, for each integer i that satisfies “2≤isN” after setting “m=n=N,” a gate of the transistor 62[i] is connected to a gate and a drain of the transistor 64[i] without being connected to a drain of the transistor 62[i] and a source and a back gate of the transistor 62[i-1]. Nis any integer of 2 or more. Except for the modification MD2E, the voltage generation circuit 2E of FIG. 25 has the same configuration as the voltage generation circuit 2D of FIG. 23. Therefore, similarly to the voltage generation circuit 2D, in the voltage generation circuit 2E, a gate of the transistor 62[1] is connected to the node NDb without being connected to the node NDa. The voltage generation circuit 2E may also provide the same effects as the voltage generation circuit 2D.
FIG. 26 shows a configuration of the voltage generation circuit 2E when “m=n=N=2.” In a case where “m=n=N=2” in the voltage generation circuit 2E, a drain of the transistor 62[1] is connected to the node NDa, a gate of the transistor 62[1] is connected to the node NDb without being connected to the node NDa, a source and a back gate of the transistor 62[1] are connected only to a drain of the transistor 62[2], a gate of the transistor 62[2] is connected to a gate of the transistor 64[2] without being connected to the drain of the transistor 62[2], and a source and a back gate of the transistor 62[2] are connected to the power supply end. In a case where “m=n=N=2” in the voltage generation circuit 2E, a drain and a gate of the transistor 64[1] are connected to the node NDb, a source and a back gate of the transistor 64[1] are connected to a drain and a gate of the transistor 64[2], and a source and a back gate of the transistor 64[2] are connected to the power supply end.

### <<Supplementary Notes>>

Supplementary notes will be provided for the present disclosure in which specific configuration examples are shown in the above-described embodiments.

A voltage generation circuit (see FIGS. 1 and 14) according to an aspect of the present disclosure has a configuration that it includes: a first MOSFET (11 or 16) including a source, a back gate, and a gate, which are connected in common to a first node (ND1 or NDa), and a drain connected to a first potential end to which a first reference voltage is applied; a front-stage transistor circuit (20 or 70) including one or more second MOSFETs (12 or 62) and connected between the first node and a second potential end to which a second reference voltage is applied; a third MOSFET (13 or 63) including a source and a back gate, which are connected in common to a second node (ND2 or NDb), a gate connected to the first node, and a drain connected to the first potential end; and a rear-stage transistor circuit (40 or 90) including one or more fourth MOSFETs (14 or 64) and connected between the second node and the second potential end, wherein the first MOSFET and the third MOSFET each have a characteristic of being in a conductive state when a gate-source voltage is 0 V, wherein the one or more second MOSFET and the one or more fourth MOSFET each have a characteristic of being in a cut-off state when a gate-source voltage is 0 V, wherein a voltage between the first reference voltage and the second reference voltage is generated at the first node by the first MOSFET and the front-stage transistor circuit, and wherein an output voltage (Vout1 or Vout2) between the first reference voltage and the second reference voltage is generated at the second node by the third MOSFET and the rear-stage transistor circuit (first configuration).

As a result, the start-up time of the voltage generation circuit may be shortened. That is, the output voltage may be directed to a desired target voltage in a short time.

In the first embodiment of the present disclosure, the power supply voltage VDD corresponds to the first reference voltage, and the ground voltage corresponds to the second reference voltage. In the second embodiment of the present disclosure, the ground voltage corresponds to the first reference voltage, and the power supply voltage VDD corresponds to the second reference voltage.

The voltage generation circuit (see FIGS. 4 and 17) of the first configuration may have a configuration that the front-stage transistor circuit includes a single second MOSFET (12 or 62), the rear-stage transistor circuit includes a single fourth MOSFET (14 or 64), a drain of the single second MOSFET is connected to the first node, a drain of the single fourth MOSFET is connected to the second node, a source and a back gate of the single second MOSFET and a source and a back gate of the single fourth MOSFET are connected to the second potential end, a gate of the single second MOSFET is connected to the first node, and a gate of the single fourth MOSFET is connected to the second node (second configuration).

The voltage generation circuit (see FIGS. 7 and 20) of the first configuration may have a configuration that the front-stage transistor circuit includes a single second MOSFET (12 or 62), the rear-stage transistor circuit includes a single fourth MOSFET (14 or 64), a drain of the single second MOSFET is connected to the first node, a drain of the single fourth MOSFET is connected to the second node, a source and a back gate of the single second MOSFET and a source and a back gate of the single fourth MOSFET are connected to the second potential end, and each of gates of the single second MOSFET and the single fourth MOSFET is connected to the second node (third configuration).

As a result, the start-up time may be further shortened.

The voltage generation circuit (see FIGS. 8 to 13 and 21 to 26) of the first configuration may have a configuration that the front-stage transistor circuit includes a plurality of second MOSFETs (12[1] to 12[m] or 62[1] to 62[m]), which are connected in series with each other between the first node and the second potential end, and the rear-stage transistor circuit includes a plurality of fourth MOSFETs (14[1] to 14[n] or 64[1] to 64[n]), which are connected in series with each other between the second node and the second potential end (fourth configuration).

The voltage generation circuit (see FIGS. 8 to 13 and 21 to 26) of the fourth configuration may have a configuration that the plurality of second MOSFETs each include a source and a back gate that are short-circuited to each other, in the plurality of second MOSFETs, a drain of one second MOSFET out of two second MOSFETs adjacent to each other is connected to a source of the other second MOSFET out of the two second MOSFETs, a drain of a specific second MOSFET (12[1] or 62[1]) among the plurality of second MOSFETs is connected to the first node, the plurality of fourth MOSFETs each include a source and a back gate that are short-circuited to each other, and a drain and a gate that are short-circuited to each other, in the plurality of fourth MOSFETs, a drain of one fourth MOSFET out of two fourth MOSFETs adjacent to each other is connected to a source of the other fourth MOSFET out of the two fourth MOSFETs, and a drain of a specific fourth MOSFET (14[1] or 64[1]) among the plurality of fourth MOSFETs is connected to the second node (fifth configuration).

The voltage generation circuit (see FIGS. 8 and 21) of the fifth configuration may have a configuration that the plurality of second MOSFETs each include a drain and a gate that are short-circuited to each other (sixth configuration).

The voltage generation circuit (see FIGS. 11 and 24) of the fifth configuration may have a configuration that the plurality of second MOSFETs include the specific second MOSFET (12[1] or 62[1]) and another second MOSFET (12[2] or 62[2]), the another second MOSFET includes a drain and a gate that are short-circuited to each other, and a gate of the specific second MOSFET is connected to the second node (seventh configuration).

As a result, the start-up time may be further shortened.

The voltage generation circuit (see FIGS. 10 and 23) of the fifth configuration may have a configuration that the plurality of second MOSFETs include the specific second MOSFET (12[1] or 62[1]) and two or more other second MOSFETs (12[2] to 12[m] or 62[2] to 62[m]), the two or more other second MOSFETs each include a drain and a gate that are short-circuited to each other, and a gate of the specific second MOSFET is connected to the second node (eighth configuration).

As a result, the start-up time may be further shortened.

The voltage generation circuit (see FIGS. 12 and 25) of the fifth configuration may have a configuration that the plurality of second MOSFETs are first to N-th front-stage transistors, the plurality of fourth MOSFETs are first to N-th rear-stage transistors, a gate of an i-th front-stage transistor is connected to a gate of an i-th rear-stage transistor, N is an integer of 2 or more, and i is a natural number of N or less (ninth configuration).

As a result, the start-up time may be further shortened.

The voltage generation circuit (see FIGS. 1 to 13) of any one of the first to ninth configurations may have a configuration that the first MOSFET, the one or more second MOSFETs, the third MOSFET, and the one or more fourth MOSFETs are N-channel MOSFETs, and the first reference voltage is higher than the second reference voltage (tenth configuration).

The voltage generation circuit (see FIGS. 14 to 26) of any one of the first to ninth configurations may have a configuration that the first MOSFET, the one or more second MOSFETs, the third MOSFET, and the one or more fourth MOSFETs are P-channel MOSFETs, and the first reference voltage is lower than the second reference voltage (eleventh configuration).

The embodiments of the present disclosure can be appropriately modified in various ways within the scope of the technical ideas shown in the claims. The above-described embodiments are merely examples of the embodiments of the present disclosure, and the meanings of the terms of the present disclosure or components are not limited to those described in the above-described embodiments. The specific numerical values shown in the above description are merely examples, and it goes without saying that they can be changed to various numerical values.

The voltage generation circuits 1 and 2 may be constructed of semiconductor integrated circuits. Any type of semiconductor device incorporating the voltage generation circuit 1 or 2 may be constructed.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A voltage generation circuit comprising:
a first MOSFET including a source, a back gate, and a gate, which are connected in common to a first node, and a drain connected to a first potential end to which a first reference voltage is applied;
a front-stage transistor circuit including one or more second MOSFETs and connected between the first node and a second potential end to which a second reference voltage is applied;
a third MOSFET including a source and a back gate, which are connected in common to a second node, a gate connected to the first node, and a drain connected to the first potential end; and
a rear-stage transistor circuit including one or more fourth MOSFETs and connected between the second node and the second potential end,
wherein the first MOSFET and the third MOSFET each have a characteristic of being in a conductive state when a gate-source voltage is 0 V,
wherein the one or more second MOSFETs and the one or more fourth MOSFETs each have a characteristic of being in a cut-off state when a gate-source voltage is 0 V,
wherein a voltage between the first reference voltage and the second reference voltage is generated at the first node by the first MOSFET and the front-stage transistor circuit, and
wherein an output voltage between the first reference voltage and the second reference voltage is generated at the second node by the third MOSFET and the rear-stage transistor circuit.

2. The voltage generation circuit of claim 1, wherein the front-stage transistor circuit includes a single second MOSFET,
wherein the rear-stage transistor circuit includes a single fourth MOSFET,
wherein a drain of the single second MOSFET is connected to the first node,
wherein a drain of the single fourth MOSFET is connected to the second node,
wherein a source and a back gate of the single second MOSFET and a source and a back gate of the single fourth MOSFET are connected to the second potential end,
wherein a gate of the single second MOSFET is connected to the first node, and
wherein a gate of the single fourth MOSFET is connected to the second node.

3. The voltage generation circuit of claim 1, wherein the front-stage transistor circuit includes a single second MOSFET,
wherein the rear-stage transistor circuit includes a single fourth MOSFET,
wherein a drain of the single second MOSFET is connected to the first node,
wherein a drain of the single fourth MOSFET is connected to the second node,
wherein a source and a back gate of the single second MOSFET and a source and a back gate of the single fourth MOSFET are connected to the second potential end, and
wherein each of gates of the single second MOSFET and the single fourth MOSFET is connected to the second node.

4. The voltage generation circuit of claim 1, wherein the front-stage transistor circuit includes a plurality of second MOSFETs, which are connected in series with each other between the first node and the second potential end, and
wherein the rear-stage transistor circuit includes a plurality of fourth MOSFETs, which are connected in series with each other between the second node and the second potential end.

5. The voltage generation circuit of claim 4, wherein the plurality of second MOSFETs each include a source and a back gate that are short-circuited to each other,
wherein in the plurality of second MOSFETs, a drain of one second MOSFET out of two second MOSFETs adjacent to each other is connected to a source of the other second MOSFET out of the two second MOSFETs,
wherein a drain of a specific second MOSFET among the plurality of second MOSFETs is connected to the first node,
wherein the plurality of fourth MOSFETs each include a source and a back gate that are short-circuited to each other, and a drain and a gate that are short-circuited to each other,
wherein in the plurality of fourth MOSFETs, a drain of one fourth MOSFET out of two fourth MOSFETs adjacent to each other is connected to a source of the other fourth MOSFET out of the two fourth MOSFETs, and
wherein a drain of a specific fourth MOSFET among the plurality of fourth MOSFETs is connected to the second node.

6. The voltage generation circuit of claim 5, wherein the plurality of second MOSFETs each include a drain and a gate that are short-circuited to each other.

7. The voltage generation circuit of claim 5, wherein the plurality of second MOSFETs include the specific second MOSFET and another second MOSFET,
wherein the another second MOSFET includes a drain and a gate that are short-circuited to each other, and
wherein a gate of the specific second MOSFET is connected to the second node.

8. The voltage generation circuit of claim 5, wherein the plurality of second MOSFETs include the specific second MOSFET and two or more other second MOSFETs,
wherein the two or more other second MOSFETs each include a drain and a gate that are short-circuited to each other, and
wherein a gate of the specific second MOSFET is connected to the second node.

9. The voltage generation circuit of claim 5, wherein the plurality of second MOSFETs are first to N-th front-stage transistors,
wherein the plurality of fourth MOSFETs are first to N-th rear-stage transistors,
wherein a gate of an i-th front-stage transistor is connected to a gate of an i-th rear-stage transistor, and
wherein N is an integer of 2 or more, and i is a natural number of N or less.

10. The voltage generation circuit of claim 1, wherein the first MOSFET, the one or more second MOSFETs, the third MOSFET, and the one or more fourth MOSFETs are N-channel MOSFETs, and
wherein the first reference voltage is higher than the second reference voltage.

11. The voltage generation circuit of claim 1, wherein the first MOSFET, the one or more second MOSFETs, the third MOSFET, and the one or more fourth MOSFETs are P-channel MOSFETs, and
wherein the first reference voltage is lower than the second reference voltage.
